(19) United States
(12) Patent Application Publication
(10) Pub. No.: US 2021/0054472 A1
(43) Pub. Date: Feb. 25, 2021

(54) METHOD FOR PRODUCING ORIENTED ELECTRICAL STEEL SHEET WITH ULTRA-LOW IRON LOSS

(71) Applicant: POSCO, Pohang-si, Gyeongsangbuk-do (KR)

(72) Inventors: Sang-Won LEE, Pohang-si, Gyeongsangbuk-do (KR); Min-Serk KWON, Pohang-si, Gyeongsangbuk-do (KR); Jin-Su BAE, Pohang-si, Gyeongsangbuk-do (KR)

(21) Appl. No.: 16/957,522

(22) PCT Filed: Dec. 6, 2018
(86) PCT No.: PCT/KR2018/015383

§ 371 Date: Jun. 24, 2020

(30) Foreign Application Priority Data
Dec. 26, 2017 (KR) 10-2017-0179749

(51) Int. Cl. C21D 8/12; C23C 16/453; C23C 16/40; C21D 9/46; C22C 38/02; C22C 38/04; C22C 38/06

(52) U.S. Cl. CPC C21D 8/12; C23C 16/453; C23C 16/40; C22C 38/06; C22C 38/02; C22C 38/04; C21D 9/46

(57) ABSTRACT

Provided is a method for producing an oriented electrical steel sheet with an ultra-low iron loss.

The method for producing an oriented electrical steel sheet according to the present disclosure comprises: a step of preparing an oriented electrical steel sheet; and a step of forming a ceramic coating layer by subjecting a gas-phase ceramic precursor to a contact reaction in a plasma state using the atmospheric pressure plasma CVD (APP-CVD) process, on a part of or the entire one or both surfaces of the electrical steel sheet.

### TECHNICAL FIELD

The present disclosure relates to a method for manufacturing an oriented electrical steel sheet.

### BACKGROUND ART

Generally, an oriented electrical steel sheet is a steel sheet containing about 3.1% of an Si element, and may have a Goss texture in which orientation of grains is arranged in a {100}<001>[0002] direction such that an oriented electrical steel sheet may have improved magnetic properties in a rolling direction. Such a {100}<001> structure may be obtained by a combination of various manufacturing processes, and a composition of a steel slab, and also heating, hot-rolling, hot-rolled sheet annealing, primary recrystallization annealing, and final-annealing of the steel slab should be strictly controlled. Specifically, an oriented electrical steel sheet may exhibit excellent magnetic properties by preventing growth of primary recrystallization grains and by a secondary recrystallization structure obtained by selectively growing a grain having {100}<001> orientation among grains of which growth has been prevented, and accordingly, a growth inhibitor for the primary recrystallization grains may be important. Also, in the final annealing process, one important matter in a technique of manufacturing an oriented electrical steel sheet is to allow grains stably having a Goss texture of {100}<001> orientation among the grains of which growth has been prevented to preferentially grow. As a growth inhibitor which may satisfy the above-described conditions and has been widely used industrially, there may be MnS, AlN, MnSe, and the like. Specifically, MnS, AlN, MnSe, and the like, contained in a steel slab, may be solid soluble by being reheated at a high temperature for a long period of time and may be hot-rolled, and the above elements having an appropriate size and distribution may be formed as a precipitate in a subsequent cooling process, and the precipitate may be used as the growth inhibitor. However, in this case, the steel slab should be heated at a high temperature, which may be a problem. With respect thereto, recently, there has been an attempt to improve magnetic properties of an oriented electrical steel sheet by a method of heating a steel slab at a low temperature. To this end, a method of adding an antimony (Sb) element to an oriented electrical steel sheet has been suggested, but sizes of grains may be non-uniform and coarse after final high-temperature annealing, such that transformer noise quality may be deteriorated, which may be a problem.

Meanwhile, to reduce power loss of an oriented electrical steel sheet, generally, an insulating film may be formed on a surface thereof, and in this case, basically, the insulating film should have high electrical insulating properties, excellent adhesiveness with a material, and uniform color without a defect on an exterior thereof. In addition thereto, as international standards for transformer noise have been strengthened and competition in the relevant industries has intensified, research into a magnetostriction phenomenon has been necessary to reduce noise of an insulating film of an oriented electrical steel sheet. Specifically, when a magnetic field is applied to an electrical steel sheet used as a transformer iron core, the steel sheet may shake by repetitive reduction and expansion, and vibration and noise may occur in a transformer due to the shaking. As for a generally known oriented electrical steel sheet, an insulating film may be formed on the steel sheet and a forsterite-based film, and tensile stress may be applied to the steel sheet using a difference in thermal expansion coefficient of the insulating film, thereby improving iron loss and obtaining an effect of reduction in noise caused by magnetostriction. However, there may be a limitation in satisfying a noise level in a high-end oriented electrical steel sheet which has recently been required. Meanwhile, as a method of reducing a 90° magnetic domain of an oriented electrical steel sheet, a wet-coating method has been used. Here, the 90° magnetic domain refers to a region having magnetization, oriented perpendicularly to a [0010] magnetic field applying direction, and the less the amount of 90° magnetic domain, the lower the magnetostriction may be. However, when a general wet-coating method is used, there may be disadvantages in which an effect of improving noise by applying tensile stress may be insufficient, and a steel sheet should be coated with a thick film having an increased coating thickness, which may degrade a space factor and efficiency of a transformer.

Other than the above-described method, as a method of providing high tension to a surface of an oriented electrical steel sheet, a coating method through vacuum deposition, such as a physical vapor deposition (PVD) method, a chemical vapor deposition (CVD) method, and the like, has been used. However, it may be difficult to use such a coating method in the industrial production, and insulating properties of an oriented electrical steel sheet manufactured by the method may be deteriorated.

### DISCLOSURE

### Technical Problem

The purpose of the present disclosure is to provide a method of manufacturing an oriented electrical steel sheet, the method including forming a ceramic coating layer on a portion or an entirety of one surface or both surfaces of the oriented electrical steel sheet by an APP-CVD method.

Also, the purpose of the present disclosure is to provide a method of manufacturing an oriented electrical steel sheet, the method including forming a ceramic coating layer on a portion or an entirety of one surface or both surfaces of the oriented electrical steel sheet on a surface of which a forsterite film is formed by an APP-CVD method.

Also, the technical issues which the present disclosure tries to address are not limited to the above-described issues, and the unmentioned other technical issues may be explicitly understood for a person skilled in the art to which the present disclosure belongs based on the disclosure as below.

### Technical Solution

A method of manufacturing an oriented electrical steel sheet according to an example embodiment of the present disclosure includes preparing an oriented electrical steel sheet; and forming a ceramic coating layer by allowing a gas-phase ceramic precursor to contact-react with a portion or an entirety of one surface or both surfaces of the oriented electrical steel sheet in a plasma state using an atmospheric pressure plasma CVD process (APP-CVD).

A method of manufacturing an oriented electrical steel sheet according to an example embodiment of the present disclosure includes preparing an electrical steel sheet on a surface of which a forsterite film is formed; and forming a ceramic coating layer by allowing a gas-phase ceramic precursor to contact-react with a portion or an entirety of one surface or both surfaces of the electrical steel sheet on a surface of which a forsterite film is formed in a plasma state using an atmospheric pressure plasma CVD process (APP-CVD).

The ceramic coating layer may be formed by, while plasma is generated by forming an electrical field on a surface of the steel sheet using a high-density radio frequency under atmospheric pressure, mixing a primary gas comprised of one or more of Ar, He, and N₂ with a gas-phase ceramic precursor, and allowing the mixture to contact-react with a surface of the electrical steel sheet.

The ceramic coating layer may be formed by adding a second gas comprised of one of H₂, O₂, and H₂O to the primary gas and the ceramic precursor and allowing the mixture to contact-react with the surface of the electrical steel sheet.

Preferably, the primary gas and the secondary gas may be heated to a temperature equal to or higher than a vaporizing point of the ceramic precursor.

When the ceramic coating layer is TiO₂, titanium isopropoxide (TTIP), Ti{OCH(CH₃)₂}₄, or TiCl₄ may be used as the ceramic precursor.

A thickness of the ceramic coating layer may be 0.1-0.6 μm, and an iron loss improvement rate for each different thickness of the coating layer may be 7-14%.

The preparing the oriented electrical steel sheet may include preparing a steel slab including, by weight %, 2.6-4.5% of silicon (Si), 0.020-0.040% of aluminum (Al), 0.01-0.20% of manganese (Mn), and a balance of Fe and inevitable impurities; manufacturing a hot-rolled sheet by heating and hot-rolling the steel slab; manufacturing a cold-rolled sheet by cold-rolling the hot-rolled sheet; obtaining a decarburized and annealed steel sheet by decarburizing and annealing the cold-rolled sheet; and coating the decarburized and annealed steel sheet with an annealing separator and performing final-annealing.

The obtaining the decarburized and annealed steel sheet by decarburizing and annealing the cold-rolled sheet may include decarburizing and nitriding the cold-rolled sheet at the same time or nitriding the cold-rolled sheet after decarburizing, and annealing the cold-rolled sheet, thereby obtaining the decarburized and annealed steel sheet.

Pre-heating and/or post-heating may be performed on the electrical steel sheet at a temperature range of 200-1250° C. before and after the APP-CVD process.

### Advantageous Effects

According to the present disclosure described above, an oriented electrical steel sheet having excellent iron loss may be effectively provided.

### DESCRIPTION OF DRAWINGS

FIG. 1 is a diagram illustrating a process of manufacturing a general oriented electrical steel sheet;

FIG. 2 is a diagram illustrating a mechanism in which a ceramic coating layer is formed on an electrical steel sheet or on a surface of an electrical steel sheet on a surface of which a forsterite film is formed using an APP-CVD process; and

FIG. 3 is an image illustrating a state in which an TTIP, one example of a ceramic precursor, is dissociated in a plasma region formed by an RF power source in an APP-CVD process.

### BEST MODE FOR INVENTION

In the description below, an example embodiment of the present disclosure will be described in detail such that a person skilled in the art to which the present disclosure belongs may easily implement the present disclosure. However, the present disclosure may be implemented in various different forms, and may not be limited to the example embodiment described herein.

A general oriented electrical steel sheet may be manufactured by undergoing a manufacturing process as below.

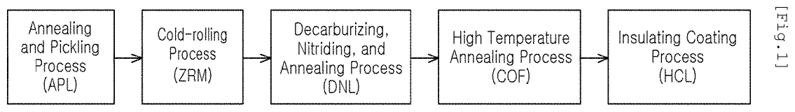

FIG. 1 is an image showing a process of manufacturing a general oriented electrical steel sheet.

As illustrated in FIG. 1, as an annealing and pickling process (APL: an annealing and pickling line), removing scale from a hot-rolled sheet, securing cold-rolling properties, and precipitating and dispersing an inhibitor (AIN) of the hot-rolled sheet advantageously for magnetic properties may be performed. Thereafter, rolling may be performed through a cold-rolling process (SendZimir Rolling Mill) to have a final product thickness which a customer company requires, and to secure crystal orientation advantageous to magnetic properties. Thereafter, [C] of a material may be removed by a decarburization and nitriding process (DNL: Decarburizing & Nitriding Line), and primary recrystallization may be formed with an appropriate temperature and nitrification reaction. Thereafter, an underlayer coating (Mg2SiO4) layer may be formed by a high-temperature annealing process (COF), and secondary recrystallization may be formed. Lastly, a material shape may be corrected through an HCL process, an annealing separator may be removed and an insulating film layer may be formed, thereby providing tension to a surface of the electrical steel sheet.

In the present disclosure, a process of forming an insulating film in the insulating and coating process (HCD) may be replaced with a process of forming a ceramic coating layer using an APP-CVD process.

In other words, as for the method of manufacturing an oriented electrical steel sheet of the present disclosure, an oriented electrical steel sheet on which a ceramic coating layer is to be coated may be prepared.

A steel composition of such an oriented electrical steel sheet and a process of manufacturing the same are not limited to any particular composition or a manufacturing process, and a generally used oriented electrical steel sheet may be manufactured using a general manufacturing process.

Preferably, the oriented electrical steel sheet may be manufactured using a process including preparing a steel slab; manufacturing a hot-rolled sheet by heating and hot-rolling the steel slab; manufacturing a cold-rolled sheet by cold-rolling the hot-rolled sheet; obtaining a decarburized and annealed steel sheet by decarburizing and annealing the cold-rolled sheet; and coating the decarburized and annealed steel sheet with an annealing separator and performing final-annealing.

The obtaining the decarburized and annealed steel sheet by decarburizing and annealing the cold-rolled sheet may include decarburizing and nitriding the cold-rolled sheet at the same time or nitriding the cold-rolled sheet after decarburizing, and annealing the cold-rolled sheet, thereby obtaining the decarburized and annealed steel sheet.

Also, in the present disclosure, the steel slab may include, by weight %, 2.6-4.5% of silicon (Si), 0.020-0.040% of aluminum (Al), 0.01-0.20% of manganese (Mn), and a balance of Fe and inevitable impurities. In the description below, compositions of the steel sheet and the reasons for limiting contents thereof as below will be described.

Si: 2.6-4.5 Weight %

Silicon (Si) may decrease iron loss by increasing specific resistance of steel. When a content of Si is excessively low, specific resistance of steel may decrease such that iron loss properties may be deteriorated, and a phase transformation section may be present in high-temperature annealing such that secondary recrystallization may become unstable, which may be a problem. When a content of Si is excessively high, embrittlement may increase such that it may be difficult to perform cold-rolling, which may be a problem. Thus, a content of Si may be adjusted within the above-mentioned range. More specifically, Si may be included by 2.6-4.5 weight %.

Al: 0.020-0.040 Weight %

Aluminum (Al) may be formed as a nitride having a form of AlN, (Al,Si)N, and (Al,Si,Mn)N finally and may work as an inhibitor. When a content of Al is excessively low, an effect of Al as an inhibitor may not be sufficiently obtained. Also, when a content of Al is excessively high, Al-based nitride may be excessively coarsely precipitated and grown such that an effect of Al as an inhibitor may be insufficient. Thus, a content of Al may be adjusted within the above-mentioned range.

Mn: 0.01-0.20 Weight %

Mn may have an effect of reducing iron loss by increasing specific resistance similarly to Si, and may be important to lead secondary recrystallization by preventing growth of primary recrystallization grains by forming a precipitate of (Al,Si,Mn)N by reacting with nitrogen introduced through a nitrification treatment, along with Si. When a content of Mn is excessively high, Mn may facilitate austenite phase transformation during hot-rolling such that a size of a primary recrystallization grain may decrease and secondary recrystallization may become unstable. Also, Mn may work as an element for forming austenite, and a fraction of austenite may increase in hot-rolling reheating such that the amount of solid solution of precipitates may increase, and accordingly, in reprecipitation, an effect of preventing primary recrystallization grains from being excessively coarse through refinement of precipitates and the formation of MnS may be insufficient, when a content of Mn is excessively low. Thus, a content of Mn may be adjusted within the above-mentioned range.

Also, in the present disclosure, the steel slab may further include 0.01-0.15 weight % of Sb, Sn, Cu, or combinations thereof.

Sb, Sn, or Cu may be grain boundary segregation elements and may interfere with movement of grains. Thus, Sb, Sn, or Cu may be important elements for controlling a grain size as Sb, Sn, or Cu may facilitate the formation of goss grains of {110}<001> orientation such that secondary recrystallization may be properly developed. When a content of each of Sb or Sn or a combination thereof is excessively low, an effect thereof may degrade, which may be a problem. When a content of each of Sb, Sn, or Cu or a combination thereof is excessively high, grain boundary segregation may excessively occur such that embrittlement of the steel sheet may increase, and breakage may occur during rolling.

In the present disclosure, an oriented electrical steel sheet on a surface of which a forsterite film is formed as a base on which the ceramic coating layer is formed may be used.

The forsterite film may be formed as magnesium oxide (MgO), a main component of a coating agent, reacts with silicon (Si) contained in the oriented electrical steel sheet in a process of coating the steel sheet with an annealing separator for preventing sticking between materials in high-temperature annealing for forming secondary recrystallization, after decarburizing and nitride-annealing are performed in a process of manufacturing the oriented electrical steel sheet.

In the present disclosure, the ceramic coating layer, described below, may be formed on at least a portion of one surface or both surfaces of the oriented electrical steel sheet on which the forsterite film is, and accordingly, an effect of film tension may be provided, and an effect of improvement in iron loss of the oriented electrical steel sheet may be maximized such that an oriented electrical steel sheet having ultra-low iron loss may be manufactured.

Thereafter, a ceramic coating layer may be formed by allowing a gas-phase ceramic precursor to contact-react with a portion or an entirety of one surface or both surfaces of the electrical steel sheet or, alternatively, with a portion or an entirety of one surface or both surfaces of the oriented electrical steel sheet on a surface of which the forsterite film is formed in a plasma state using an atmospheric pressure plasma CVD process (APP-CVD).

In the present disclosure, a process used for forming the ceramic coating layer may be referred to as an atmospheric pressure plasma enhanced-chemical vapor deposition (APP-CVD) process.

In the APP-CVD, density of radical may be higher than those of a general CVD, a low pressure CVD (LPCVD), an atmospheric pressure CVD (APCVD), and plasma enhanced CVD (PECVD) such that a deposition rate may be high. Also, differently from a general CVD, a vacuum facility based on high vacuum or low vacuum may not be necessary such that facility costs may be low, which may be advantageous. In other words, as no vacuum facility is necessary, it may be relatively easy to drive a facility, and deposition performance may be excellent.

Also, in the APP-CVD process of the present disclosure, while plasma is generated by forming an electrical field on a surface of the steel sheet using a high-density radio frequency under an atmospheric pressure condition, a primary gas comprised of one or more of Ar, He, and N₂, which is a main gas, may be mixed with a gas-phase ceramic precursor, and the mixture may be provided to a reactor and may be contact-react with a surface of the steel sheet.

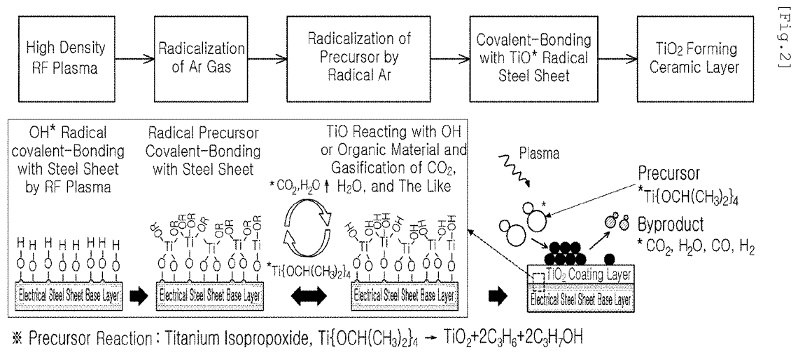

FIG. 2 is a diagram illustrating a mechanism in which a ceramic coating layer is formed on an electrical steel sheet or on a surface of an electrical steel sheet on a surface of which a forsterite film is formed using an APP-CVD process.

As illustrated in FIG. 2, in the APP-CVD process, an electrical field may be formed on one surface or both surfaces of the steel sheet using a high-density radio frequency (e.g., 13.56 MHz) under atmospheric pressure. Also, when a primary gas such as one or more of Ar, He, or N₂ is sprayed through a hole, a line, or a surface nozzle, electrons may be separated under an electrical field and may become radical, and may exhibit polarity.

In the present disclosure, in some cases, a plurality of line sources or 2D square sources may be used as an RF plasma source. That is, a type of source may be different depending on an optimized coating speed and a moving speed of a base layer.

Then, Ar radical and electrons may move back and forth in a reactor under alternating current of 50-60 Hz between the RF power source and the steel sheet, may collide with a gas-phase ceramic precursor (e.g., TTIP: titanium isopropoxide, Ti{OCH(CH₃)₂}₄) mixed with the primary gas such that the precursor may be dissociated, and a radical of the precursor may be formed.

In this case, in the present disclosure, the ceramic precursor such as TTIP may be mixed with the primary gas comprised of one or more of Ar, He, and N₂, may passes through the RF power source and a gas spraying nozzle, and may flow into a reactor.

The ceramic precursor such as a TTIP may be preserved in a liquid state, and may be vaporized through a heating process of 50-100° C. Also, when the primary gas passes through a region including a TTIP, the primary gas may be mixed with the ceramic precursor, may passes through the RF power source and the gas spraying nozzle, and may flow into a reactor.

As the ceramic precursor in the present disclosure, various types of ceramic precursors may be used as long as the precursor is in a liquid state and may be easily vaporized when being heated at a relatively not high temperature. For example, TTIP, TiCL₄, TEOT, or the like, may be used. In other words, in the present disclosure, when the ceramic coating layer is TiO₂, a titanium isopropoxide (TTIP), Ti{OCH(CH₃)₂}₄, TiCl₄, or the like, may be used as the ceramic precursor.

In this case, in the present disclosure, to improve quality of a coating layer, if desired, a secondary gas, an auxiliary gas, comprised of one of O₂, H₂, and H₂O may be added along with the primary gas to improve purity of the coating layer. In other words, to improve quality of a coating layer, a secondary gas may be added, and an unnecessary coating layer may be removed by reaction with the gas. In the present disclosure, whether to add the secondary gas may be determined depending on overall conditions such as whether a base layer is heated, or the like.

As described above, in the present disclosure, the liquid ceramic precursor may be heated to a temperature equal to or higher than a vaporization point through a heating device, and the primary gas and the secondary gas may be heated to a temperature equal to or higher than a vaporization point of the ceramic precursor in advance through a steam heating device or an electrical heating device, may be mixed with the ceramic precursor, and may be supplied to a reactor in a gaseous state, thereby supplying a vaporized ceramic precursor gas to the plasma source.

In this case, it may be preferable to form the ceramic coating layer using the primary gas, the secondary gas, and the ceramic precursor by 100-10,000 SLM, 0-1,000 SCCM, 10-1,000 SLM, respectively.

Also, in the present disclosure, a dissociated radical may collide with an oriented electrical steel sheet exhibiting ground or (−) electrode such that a ceramic coating layer (e.g., TiO₂) may be formed on a surface.

As for the principle of generating plasma in the present disclosure, electrons may be accelerated under an electrical field provided by a high-density RF power source, and the electrons may collide with neural particles such as atoms, molecules, and the like, such that ionization, excitation, and dissociation may occur. In this case, activated species and radicals formed by excitation and dissociation may react with each other, thereby forming a final ceramic coating layer.

Although exact layering equipment is not disclosed, in the case of ceramic TiO₂ layering equipment, for example, a TTIP, a ceramic precursor, may be ionized as below by plasma under an electrical field and may be layered on a surface of a base layer.

Ti(OR)₄→Ti*(OH)ₓ₋₁(OR)₄₋ₓ→(HO)ₓ(RO)₃₋ₓTi—O—Ti(OH)ₓ₋₁(OR)₄₋₁→Ti—O—Ti network

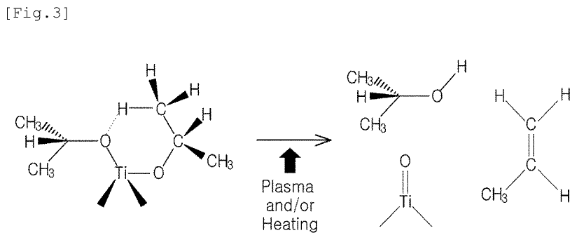

FIG. 3 is an image illustrating a state in which an TTIP, one example of a ceramic precursor, is dissociated in a plasma region formed by an RF power source in an APP-CVD process.

Meanwhile, in the present disclosure, to layer steel sheets each having a width of 1 m, which moves at a speed of 100 mpm, in a thickness of 0.05-0.5 μm using an APP-CVD, 500 kW-10 MW of an RF power source may be necessary. Also, one or a plurality of RF power sources may stably maintain an electrical field by a power matching system.

Also, in the present disclosure, a thickness of the ceramic coating layer may be 0.1-0.6 μm preferably, and an iron loss improvement rate depending on the thickness of the coating layer may be 7-14%.

Also, a heat treatment may be necessary to provide a finally intended tension to the layered ceramic coating layer if desired. In other words, pre-heating and/or post-heating may be performed on the electrical steel sheet at a temperature range of 200-1250° C. before and after the APP-CVD process preferably to improve a layering speed and quality.

### MODE FOR INVENTION

The present disclosure will be described through an example embodiment.

### Embodiment

A steel slab including 3.4 weight % of silicon (Si), 0.03 weight % of aluminum (Al), 0.10 weight % of manganese (Mn), 0.05 weight % of antimony (Sb), 0.05 weight % of tin (Sn), 0.05 weight % of copper (Cu), and a balance of Fe and inevitable impurities was prepared.

Thereafter, the steel slab was heated at 1150° C. for 220 minutes and was hot-rolled to have a thickness of 2.3 mm, thereby manufacturing a hot-rolled sheet. The hot-rolled sheet was heated to 1120° C., maintained at 920° C. for 95 seconds, rapidly cooled in water, pickled, and cold-rolled to have a thickness of 0.27 mm, thereby manufacturing a cold-rolled sheet.

The cold-rolled sheet was inserted into a furnace maintained at 850° C., a dew point temperature and oxidation potential were adjusted, and decarburizing, nitriding and a primary recrystallization annealing process were performed at the same time in an atmosphere of mixture gas of hydrogen, nitrogen, and ammonia, thereby manufacturing a decarburized and annealed steel sheet.

Thereafter, slurry was manufactured by mixing distilled water with an annealing separator including MgO as a main component, and the decarburized and annealed steel sheet was coated with the slurry using a roll, or the like, and final annealing was performed. In the final annealing, a primary soaking temperature was 700° C., a secondary soaking temperature was 1200° C., and a temperature rising rate was 15° C./hr in a temperature rising section. Also, an atmosphere of mixture gas of 25 volume % of nitrogen and 75 volume % of hydrogen was used up to 1200° C., and after the steel sheet reached 1200° C., the steel sheet was maintained at an atmosphere of hydrogen gas of 100 volume % for 15 hours, and was furnace-cooled.

Thereafter, the annealing separator on surfaces of the electrical steel sheets manufactured as above was removed, and a ceramic coating layer was formed using an APP-CVD process.

Specifically, the oriented electrical steel sheet was indirectly heated to a temperature of 500° C. before the APP-CVD process, and the steel sheet was put into a APP-CVD reactor.

In this process, an electrical field was formed on one surface or both surfaces of the oriented electrical steel sheet using a radio frequency of 13.56 MHz under atmospheric pressure, and an Ar gas was put in the reactor. Thereafter, an TTIP, a liquid ceramic precursor, was heated and vaporized under alternating power of 50-60 Hz between an RF power source and a steel sheet, the ceramic precursor was mixed with the Ar gas and an H2 gas, and the mixture was put into the reactor to form TiO2 ceramic coating layers having different thicknesses on surfaces of the electrical steel sheets.

Magnetic properties of the electrical steel sheets on which the ceramic coating layers having different thicknesses were formed were examined under conditions of 1.7 T and 50 Hz. Generally, as for magnetic properties of the electrical steel sheet, W17/50 and B8 are used as representative values. W17/50 refers to power loss occurring when a magnetic field of a frequency of 50 Hz was magnetized up to 1.7 Tesla in an alternating manner. Here, Tesla is a unit of magnetic flux density indicating a magnetic flux per unit area. B8 indicates a value of magnetic flux density flowing in the electrical steel sheet when a current of 800 A/m flows in a coil wound around the electrical steel sheet.

TABLE 1

| | | Coated | Iron Loss | Magnetic |
|---|---|---|---|---|
| | Coating | Thickness | (W17/50, | Flux Density |
| Classification | Material | (μm) | W/kg) | (B8, T) |
| Comparative | Forsterite | — | 0.94 | 1.908 |
| Example 1 | Film (non- | | | |
| | coated) | | | |
| Comparative | Coating | 3.0 | 0.89 | 1.907 |
| Example 2 | Colloid Silica/ | | | |
| | Magnesium | | | |
| | Phosphate | | | |
| | (1:1) | | | |
| Inventive | TiO2 | 0.2 | 0.84 | 1.912 |
| Example 1 | | | | |
| Inventive | TiO2 | 0.5 | 0.80 | 1.915 |
| Example 2 | | | | |
| Inventive | TiO2 | 1.0 | 0.73 | 1.913 |
| Example 3 | | | | |
| Inventive | TiO2 | 1.5 | 0.75 | 1.913 |
| Example 4 | | | | |
| Inventive | TiO2 | 2.0 | 0.74 | 1.911 |
| Example 5 | | | | |

As indicated in Table 1 above, inventive examples 1-4 in which the TiO₂ ceramic coating layers were formed on the forsterite films using the APP-CVD process exhibited more excellent magnetic properties than comparative example 1 in which such the coating was not performed.

Further, inventive examples 1-4 in which the TiO₂ ceramic coating layers were formed using the APP-CVD process exhibited more excellent iron loss properties than comparative example 2 in which the colloid silica/magnesium phosphate (1:1) film was formed.

While the example embodiments have been shown and described above, it will be apparent to those skilled in the art that modifications and variations could be made without departing from the scope of the present disclosure as defined by the appended claims.

1. A method of manufacturing an oriented electrical steel sheet, the method comprising:
preparing an oriented electrical steel sheet; and
forming a ceramic coating layer by allowing a gas-phase ceramic precursor to contact-react with a portion or an entirety of one surface or both surfaces of the oriented electrical steel sheet in a plasma state using an atmospheric pressure plasma CVD process (APP-CVD).

2. The method of claim 1, wherein the ceramic coating layer is formed by, while plasma is generated by forming an electrical field on a surface of the steel sheet using a high-density radio frequency under atmospheric pressure, mixing a primary gas comprised of one or more of Ar, He, and N₂ with a gas-phase ceramic precursor, and allowing the mixture to contact-react with a surface of the electrical steel sheet.

3. The method of claim 2, wherein the ceramic coating layer is formed by adding a second gas comprised of one of H₂, O₂, and H₂O to the primary gas and the ceramic precursor and allowing the mixture to contact-react with the surface of the electrical steel sheet.

4. The method of claim 3, wherein the primary gas and the secondary gas are heated to a temperature equal to or higher than a vaporizing point of the ceramic precursor.

5. The method of claim 1, wherein, when the ceramic coating layer is TiO₂, titanium isopropoxide (TTIP), Ti{OCH(CH₃)₂}₄, or TiCl₄ is used as the ceramic precursor.

6. The method of claim 1, wherein a thickness of the ceramic coating layer is 0.1-0.6 μm, and an iron loss improvement rate depending on the thickness of the coating layer is 7-14%.

7. The method of claim 1, wherein the preparing the oriented electrical steel sheet includes:
preparing a steel slab including, by weight %, 2.6-4.5% of silicon (Si), 0.020-0.040% of aluminum (Al), 0.01-0.20% of manganese (Mn), and a balance of Fe and inevitable impurities;
manufacturing a hot-rolled sheet by heating and hot-rolling the steel slab;
manufacturing a cold-rolled sheet by cold-rolling the hot-rolled sheet;
obtaining a decarburized and annealed steel sheet by decarburizing and annealing the cold-rolled sheet; and
coating the decarburized and annealed steel sheet with an annealing separator and performing final-annealing.

8. The method of claim 7, wherein the obtaining the decarburized and annealed steel sheet by decarburizing and annealing the cold-rolled sheet includes decarburizing and nitriding the cold-rolled sheet at the same time or nitriding the cold-rolled sheet after decarburizing, and annealing the cold-rolled sheet, thereby obtaining the decarburized and annealed steel sheet.

9. The method of claim 1, wherein pre-heating and/or post-heating is performed on the electrical steel sheet at a temperature range of 200-1250° C. before and after the APP-CVD process.

10. A method of manufacturing an oriented electrical steel sheet, the method comprising:
preparing an electrical steel sheet on a surface of which a forsterite film is formed; and
forming a ceramic coating layer by allowing a gas-phase ceramic precursor to contact-react with a portion or an entirety of one surface or both surfaces of the electrical steel sheet on a surface of which a forsterite film is formed in a plasma state using an atmospheric pressure plasma CVD process (APP-CVD).

11. The method of claim 10, wherein the ceramic coating layer is formed by, while plasma is generated by forming an electrical field on a surface of the electrical steel sheet using a high-density radio frequency under atmospheric pressure, mixing a primary gas comprised of one or more of Ar, He, and N₂ with a gas-phase ceramic precursor, and allowing the mixture to contact-react with a surface of the electrical steel sheet.

12. The method of claim 11, wherein the ceramic coating layer is formed by adding a second gas comprised of one of H₂, O₂, and H₂O to the primary gas and the ceramic precursor and allowing the mixture to contact-react with the surface of the electrical steel sheet.

13. The method of claim 12, wherein the primary gas and the secondary gas are heated to a temperature equal to or higher than a vaporizing point of the ceramic precursor.

14. The method of claim 10, wherein, when the ceramic coating layer is TiO₂, titanium isopropoxide (TTIP), Ti{OCH(CH₃)₂}₄, or TiCl₄ is used as the ceramic precursor.

15. The method of claim 10, wherein a thickness of the ceramic coating layer is 0.1-0.6 μm, and an iron loss improvement rate for each different thickness of the coating layer is 7-14%.

16. The method of claim 10, wherein the preparing the oriented electrical steel sheet includes:
preparing a steel slab including, by weight %, 2.6-4.5% of silicon (Si), 0.020-0.040% of aluminum (Al), 0.01-0.20% of manganese (Mn), and a balance of Fe and inevitable impurities;
manufacturing a hot-rolled sheet by heating and hot-rolling the steel slab;
manufacturing a cold-rolled sheet by cold-rolling the hot-rolled sheet;
obtaining a decarburized and annealed steel sheet by decarburizing and annealing the cold-rolled sheet; and
coating the decarburized and annealed steel sheet with an annealing separator and performing final-annealing.

17. The method of claim 16, wherein the obtaining the decarburized and annealed steel sheet by decarburizing and annealing the cold-rolled sheet includes decarburizing and nitriding the cold-rolled sheet at the same time or nitriding the cold-rolled sheet after decarburizing, and annealing the cold-rolled sheet, thereby obtaining the decarburized and annealed steel sheet.

18. The method of claim 10, wherein pre-heating and/or post-heating is performed on the electrical steel sheet at a temperature range of 200-1250° C. before and after the APP-CVD process.
